(19) United States
(12) Patent Application Publication
(10) Pub. No.: US 2018/0233662 A1
(43) Pub. Date: Aug. 16, 2018

(54) SYSTEMS AND METHODS FOR PATTERNING OF HIGH DENSITY STANDALONE MRAM DEVICES

(71) Applicant: Lam Research Corporation, Fremont, CA (US)

(72) Inventors: Ivan L. Berry, III, San Jose, CA (US); Thorsten Lill, Santa Clara, CA (US)

(21) Appl. No.: 15/893,908

(22) Filed: Feb. 12, 2018

Related U.S. Application Data
(60) Provisional application No. 62/458,617, filed on Feb. 14, 2017.

(51) Int. Cl. H01L 43/12; H01L 43/08; H01L 27/22; H01L 43/02; G11C 11/16; H01F 10/32; H01F 41/34

(52) U.S. Cl. CPC H01L 43/12; H01L 43/08; H01L 27/222; H01F 41/34; G11C 11/161; H01F 10/3254; H01L 43/02

(57) ABSTRACT

A method for processing a substrate including a magnetoresistive random access memory (MRAM) stack includes providing a substrate including the MRAM stack and creating a first mask layer on a surface of the MRAM stack. The first mask layer defines a first mask pattern including a first plurality of spaced mask lines extending in a first direction across the surface of the MRAM stack and first spaces located between the first plurality of spaced mask lines. The method further includes performing ion beam etching in the first direction in the first spaces located between the first plurality of spaced mask lines to remove material of the MRAM stack located below the first spaces.

### CROSS-REFERENCE TO RELATED APPLICATIONS

This application claims the benefit of U.S. Provisional Application No. 62/458,617, filed on Feb. 14, 2017. The entire disclosure of the application referenced above is incorporated herein by reference.

### FIELD

The present disclosure relates to substrate processing systems and methods and more particularly to substrate processing systems and methods for patterning of MRAM devices using ion beam etching.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Electronic devices use integrated circuits including memory to store data. One type of memory that is commonly used in electronic circuits is dynamic random-access memory (DRAM). DRAM stores each bit of data in separate capacitors of an integrated circuit. The capacitors can be either charged or discharged, representing the two states of a bit. Since non-conducting transistors leak, the capacitors will slowly discharge, and the information eventually fades unless the capacitor charge is refreshed periodically. Refreshing the memory consumes additional power.

Each DRAM cell includes a transistor and a capacitor as compared to four or six transistors in static RAM (SRAM). This allows DRAM to reach very high storage densities. Unlike flash memory, DRAM is volatile memory (vs. non-volatile memory), since data is lost when power is removed. DRAM has to be refreshed every few milliseconds and as a result contributes to up to 40% of the energy consumption in data centers.

Several emerging memory devices such as magnetoresistive RAM (MRAM) are potential replacements for DRAM. Currently, MRAM structures are patterned using a dot type mask. Because the MRAM stack materials are highly non-volatile, ion beam etching (IBE) is used to etch the structures. The dot type masks create round pillar structures.

IBE yields are impact angle dependent. As device density increases, aspect ratios increase and an ion impact angle becomes very shallow (ions strike the feature sidewall surface at a glancing angle). At the same time, the impact angle to a bottom layer becomes steeper, which causes poor bottom layer selectivity. Finally, the direction of the sputtered atoms has a strong component that is vertical to the etched surface, which results in re-deposition on opposing etched walls.

### SUMMARY

A method for processing a substrate including a magnetoresistive random access memory (MRAM) stack includes providing a substrate including the MRAM stack and creating a first mask layer on a surface of the MRAM stack. The first mask layer defines a first mask pattern including a first plurality of spaced mask lines extending in a first direction across the surface of the MRAM stack and first spaces located between the first plurality of spaced mask lines. The method further includes performing ion beam etching in the first direction in the first spaces located between the first plurality of spaced mask lines to remove material of the MRAM stack located below the first spaces.

In other features, the method includes depositing gap fill material on the substrate. Depositing the gap fill material on the substrate includes depositing a conformal silicon nitride layer on the substrate; and depositing silicon dioxide layer on the silicon nitride layer.

In other features, depositing the gap fill material on the substrate includes depositing a silicon nitride layer on the substrate. In other features, the method includes removing overburden. Removing the overburden comprises performing chemical mechanical polishing (CMP).

In other features, the method includes creating a second mask layer on the substrate. The second mask layer defines a second mask pattern including a second plurality of spaced mask lines that extend in a second direction across the surface of the MRAM stack and second spaces that are located between the second plurality of spaced mask lines. The second direction is transverse to the first direction.

In other features, the method includes performing ion beam etching in the second direction in the second spaces located between the second plurality of spaced mask lines to remove material of the MRAM stack located below the second spaces and to create an array of rectangular MRAM stacks. The method includes depositing gap fill material on the substrate between the MRAM stacks.

In other features, depositing the gap fill material on the substrate includes depositing a conformal silicon nitride layer on the substrate; and depositing silicon dioxide on the silicon nitride layer. In other features, depositing the gap fill material on the substrate includes depositing silicon nitride on the substrate.

In other features, the method includes removing overburden and the second mask pattern. The overburden and the second mask pattern are removed using chemical mechanical polishing (CMP). The method includes using ion beam etching to trim between the array of rectangular MRAM stacks.

A method for processing a substrate including a magnetoresistive random access memory (MRAM) stack includes providing a substrate including a magnetoresistive random access memory (MRAM) stack arranged on an underlying layer. The method includes creating a first mask layer on the substrate to define a first line and space mask pattern and performing first ion beam etching in spaces of the first line and space mask pattern to create a plurality of spaced, elongate MRAM stacks that extend across the substrate. The method includes creating a second mask layer to define a second line and space mask pattern arranged in a direction transverse to the first line and space mask pattern and performing second ion beam etching in spaces of the second line and space mask pattern to create an array of spaced, rectangular MRAM stacks on the substrate.

In other features, the method includes, prior to creating the second mask layer on the substrate, depositing gap fill material on the substrate and removing overburden. Depositing the gap fill material on the substrate includes depositing a conformal silicon nitride layer on the substrate; and depositing silicon dioxide layer on the silicon nitride layer.

In other features, depositing the gap fill material on the substrate includes depositing a silicon nitride layer on the substrate. After performing the second ion beam etching, the method includes depositing gap fill material on the substrate between the array of spaced, rectangular MRAM stacks.

In other features, depositing the gap fill material on the substrate includes depositing a conformal silicon nitride layer on the substrate; and depositing silicon dioxide on the silicon nitride layer. Depositing the gap fill material on the substrate includes depositing silicon nitride on the substrate.

In other features, the method includes removing overburden and the second mask pattern. The method includes using ion beam etching to trim between the array of spaced, rectangular MRAM stacks.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an ion beam etching system according to the present disclosure;

FIG. 2 is a side cross-sectional view of an example of a substrate including an MRAM stack according to the present disclosure;

FIG. 3 is a perspective view of an example of the substrate including the MRAM stack during a first IBE step according to the present disclosure;

FIG. 4 is a perspective view of an example of the substrate including the MRAM stack after SiN deposition and SiO₂ gapfill according to the present disclosure;

FIG. 5 is a perspective view of an example of the substrate including the MRAM stack during a second IBE step according to the present disclosure;

FIG. 6 is a perspective view of an example of the substrate including the MRAM stack after the second IBE step according to the present disclosure;

FIG. 7 is a perspective view of an example of the substrate including the MRAM stack after SiN deposition and SiO₂ gapfill according to the present disclosure;

FIG. 8 is a perspective view of an example of the substrate including the MRAM stack after removal of overburden and the second hardmask according to the present disclosure;

FIG. 9 is a perspective view of an example of the substrate including the MRAM stack after an IBE trim step according to the present disclosure; and

FIG. 10 is a flowchart illustrating a method for patterning of high density standalone MRAM devices.

In the drawings, reference numbers may be reused to identify similar and/or identical elements.

### DETAILED DESCRIPTION

The present disclosure relates to systems and methods for forming MRAM devices with a high density. Densely packed MRAM devices are formed using IBE and a self-aligned patterning scheme. Line and space masks are used in sequence to form MRAM pillars. Due to the properties of IBE, denser device structures can be created. If the MRAM stack includes a selector layer to prevent parasitic currents, the resulting device is a MRAM cross point memory and can be stacked for increased device density.

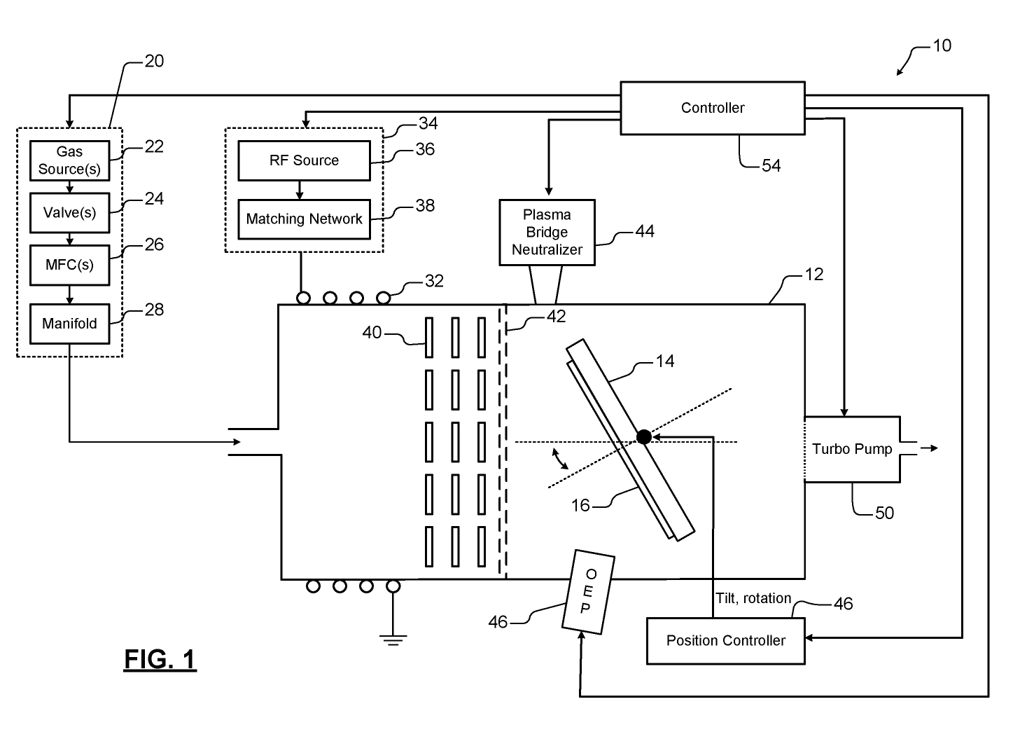

Referring now to FIG. 1, an IBE substrate processing system 10 is shown. The IBE substrate processing system 10 includes a processing chamber 12 with a substrate fixture 14 for supporting a substrate 16 such as a semiconductor wafer. The substrate 16 can be attached to the substrate fixture 14 using any suitable approach. In some examples, the substrate 16 is mechanically or electrostatically connected to the substrate fixture 14. In some examples, the substrate fixture 14 provides precise tilting and rotation and may include an electrostatic chuck (ESC) to engage the substrate 16.

A gas delivery system 20 selectively delivers one or more gas mixtures to the processing chamber 12. The gas delivery system 20 includes one or more gas sources 22, valves 24, mass flow controllers (MFC) 26 and a mixing manifold 28 that are in fluid communication with the processing chamber 12. An inductive coil 32 may be arranged around an outer wall of the processing chamber 12 at one end of the processing chamber 12. A plasma generator 34 selectively supplies RF power to the inductive coil 32. The plasma generator 34 may include an RF source 36 and a matching network 38. In use, the gas mixture is supplied to the processing chamber 12 and RF power is supplied to the inductive coil 32 to strike plasma in the processing chamber 12. The plasma produces ions.

An ion extractor 40 such as a 3-grid optic system is arranged adjacent to a mechanical shutter 42. The ion extractor 40 extracts positive ions from the plasma and accelerates the positive ions in a beam towards the substrate 16. A plasma bridge neutralizer 44 supplies electrons e⁻ into the processing chamber 12 to neutralize a charge of the ion beam passing through the ion extractor 40 and mechanical shutter 42.

A position controller 48 may be used to control a position of the substrate fixture 14. In particular, the position controller 48 controls a tilt angle about a tilt axis and rotation of the substrate fixture 14 to position the substrate 16. An optical endpoint 46 may be used to sense a location of the ion beam relative to the substrate 16 and/or substrate fixture 14. A turbo pump 50 may be used to control pressure in the processing chamber 12 and/or to evacuate reactants from the processing chamber 12. A controller 54 may be used to control the plasma generator 34, the gas delivery system 20, the plasma bridge neutralizer 44, the position controller 48 and/or the turbo pump 50.

Referring now to FIG. 2, a substrate 150 includes one or more underlying layers 154 and an MRAM stack 158 including a free layer 160, a magnesium oxide (MgO) layer 162 and a reference layer 164, each of which may include one or more sub-layers (not shown). During processing, a first hard mask layer 170 may be deposited on the reference layer 164 to pattern the underlying MRAM stack 158. The position of the free layer 160 and the reference layer 164 can also be reversed in which case the first hard mask layer 170 would be deposited on top of the free layer 160.

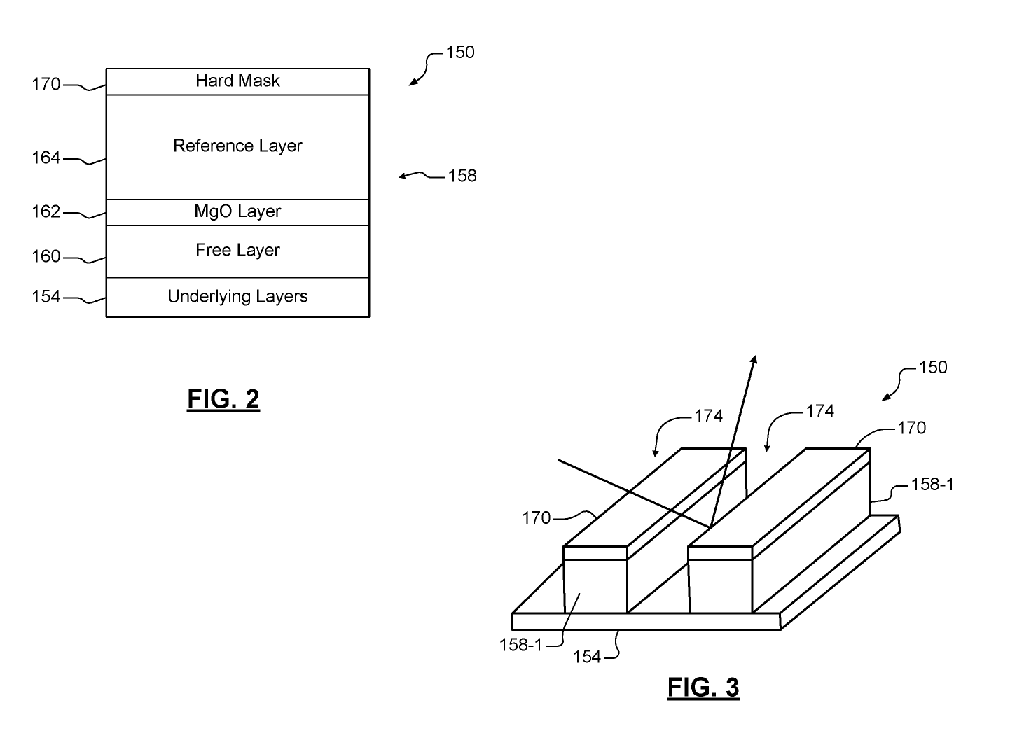

Referring now to FIG. 3, the first hard mask layer 170 is deposited and patterned on the MRAM stack 158 using a line and space pattern arranged in a first direction. In some examples, the first hard mask layer 170 is made of tungsten (W), tantalum (Ta), tantalum nitride (TaN), titanium nitride (TiN) or other refractory metals. In some examples, the first hard mask layer 170 is patterned using a carbon mask and reactive ion etching.

As can be appreciated, the ion impact angle towards an etch front is not limited when patterning using lines and spaces. IBE is used to remove material located in the spaces between the adjacent lines of the mask in the first direction. For example, IBE is used to remove the MRAM stack 158 down to the underlying layers 154 in the first direction. As a result of the IBE process, the MRAM stacks 158 are separated into a plurality of elongated and spaced MRAM stacks 158-1 extending in the first direction.

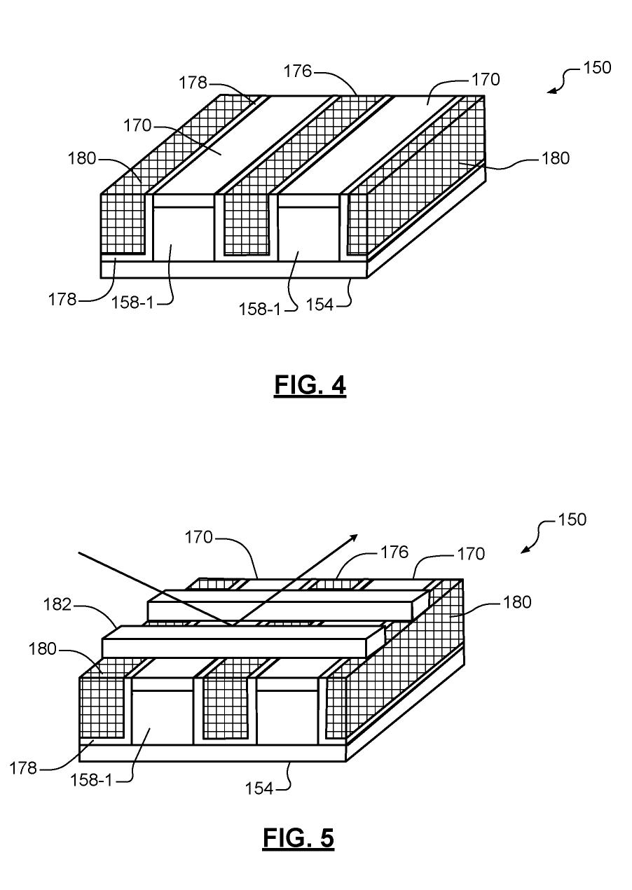

Referring now to FIG. 4, after the first IBE is performed, a silicon nitride (SiN) layer 178 is deposited on the structures shown in FIG. 3. In some examples, the SiN layer 178 is deposited using a conformal deposition process. In some examples, the conformal deposition process includes chemical vapor deposition (CVD) or atomic layer deposition (ALD) either with or without plasma enhancement.

After depositing the SiN layer 178, a silicon-containing layer 180 such as silicon dioxide is deposited to gapfill elongate regions between the MRAM stacks 158. While a combination of a SiN layer and SiO₂ gapfill is described herein, SiN can also be used for gapfill instead of SiO₂. After depositing the silicon-containing layer 180, overburdened can be removed. In some examples, the overburdened is removed using chemical mechanical polishing (CMP) or etching.

Referring now to FIG. 5, a second hard mask layer 182 is deposited on the structures shown in FIG. 4 in a direction transverse to the first hard mask layer 170. The second hard mask layer 182 also has a line and space pattern that is arranged transversely to the line and space pattern of the first hard mask layer 170. In some examples, reactive ion etch is used to pattern the first hard mask layer 170 and second hard mask layer 182 using a carbon mask. During this process step, hardmask material from the first patterning step is exposed and removed. IBE is performed to remove material located in spaces between the adjacent lines of the second hard mask layer 182 and to create standalone MRAM stacks 158-2.

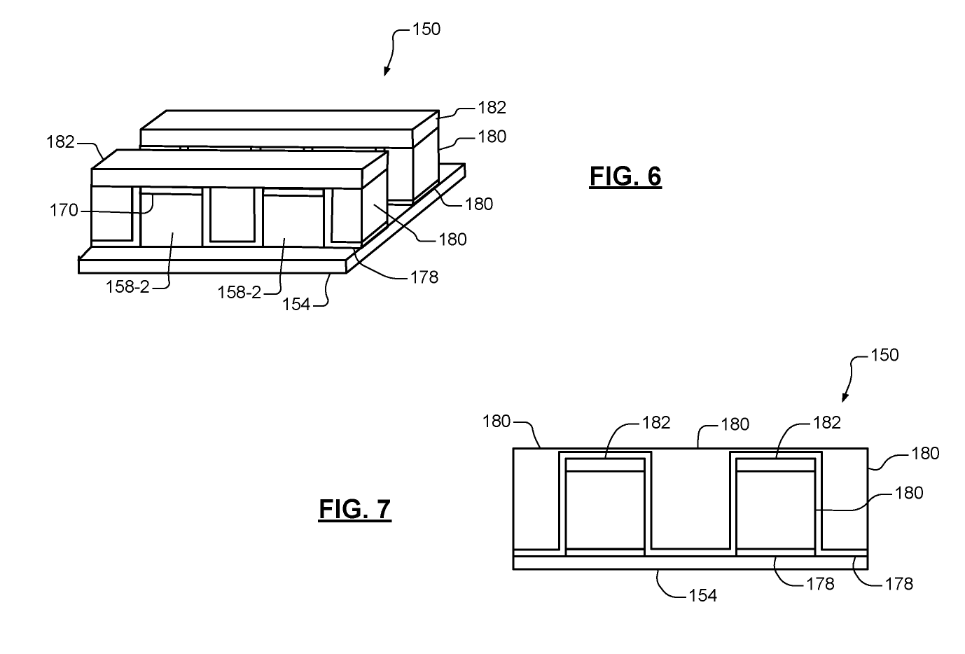

Referring now to FIG. 6-8B, after the second IBE is performed, the SiN layer 178 is deposited on the structures shown in FIG. 5. In some examples, the SiN layer 178 is deposited using the conformal deposition process. After depositing the SiN layer 178, the silicon-containing layer 180 such as SiO₂ or SiN is deposited to gapfill elongate regions between the MRAM stacks 158 as can be seen in FIG. 7. In FIGS. 8A and 8B, overburdened is removed down to the first hard mask layer 170. In this process, the second hardmask layer is removed.

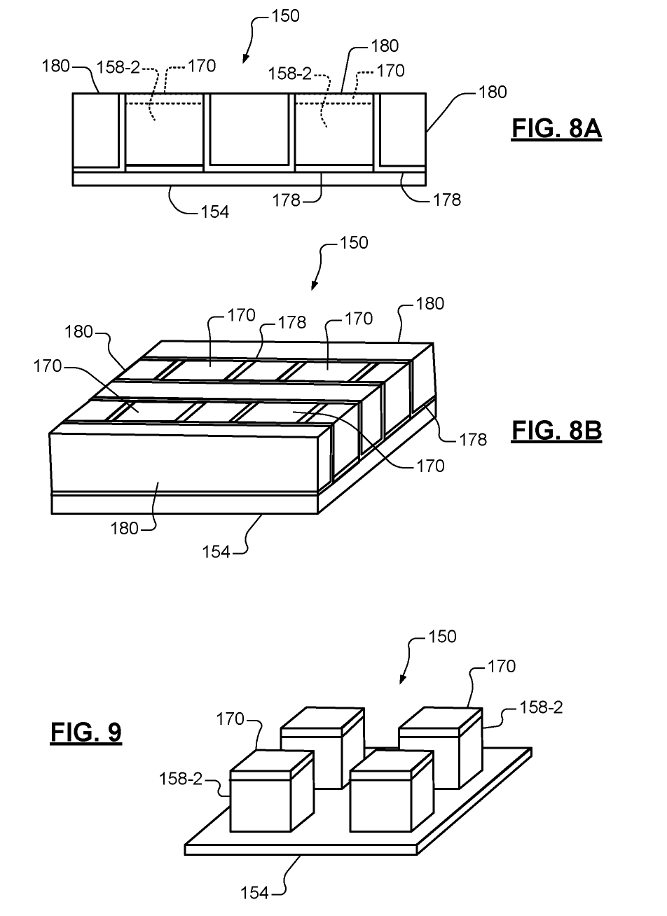

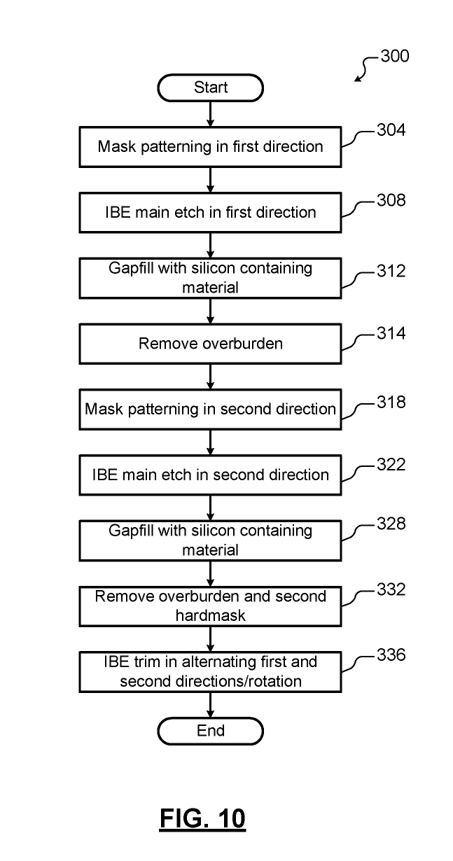

Referring now to FIG. 9, IBE is used to remove material around the MRAM stacks 158-2. After main etch, backsputtered and damaged material is typically located on sidewalls of the MRAM stacks 158-2. The material is removed during a low power trim step. The sacrificial gapfill allows the sidewall to be trimmed while not backsputtering conductive material because the etch front includes silicon-containing material.

Referring now to FIG. 10, a method 300 for processing a substrate including MRAM stacks using IBE is shown. At 304, a line and space mask is used to pattern the substrate in a first direction. At 308, IBE is used to perform etching in spaces between the mask lines in the first direction. At 312, a silicon-containing material (for example as SiN and/or SiO₂) is used to gap fill between the MRAM stacks. At 314, the overburdened is removed. At 318, a line and space mask is used to pattern the substrate in a second direction that is transverse to the first direction.

At 322, IBE is used to perform etching in the spaces between the lines in the second direction. At 328, a silicon-containing material is used to gap fill between the MRAM stacks. At 332, overburden and the second hardmask are removed. At 336, IBE is used to trim between the MRAM stacks in alternating first and second directions with or without rotation of the substrate.

The IBE method according to the present disclosure uses a first hard mask that is formed with a line and space pattern. The hard mask can be made from tungsten (W), titanium (Ti), tantalum (Ta), titanium nitride (TiN) or other refractory metals. The IBE proceeds along spaces between the mask lines. The main component of the sputtered atoms is a direction of the mask lines (e.g. forward sputtering). The atoms leave the substrate travelling along the lines. After patterning, the lines are encapsulated in-situ with SiN or other suitable encapsulation layers. The encapsulation prevents MgO damage due to air exposure. After encapsulation, the just-formed trench is filled with a suitable dielectric either in situ or in a standalone tool.

A second line and space mask is formed perpendicular to the first mask. The IBE process is repeated. In some examples, the sputtering conditions are selected to give 1:1 selectivity to between the MRAM stack and the dielectric fill material and at the same time maximum selectivity to the mask made from refractory material. After IBE, the structure is sealed with an encapsulation layer and the gap is filled.

In some examples, the MRAM stack includes a selector device and a refractory metal layer at the bottom. In that manner, a refractory metal layer (for instance tungsten) is formed after etching of the entire stack. In another method, the bottom W layer can be etched with reactive ion etching (RIE) after encapsulation. The resulting W lines are the wordlines of the memory device.

In some examples, a perpendicular refractory metal mask (for instance W or Ta) is formed and the patterning is repeated. The remaining mask forms the contacts to a bitline, which can be patterned on top the memory device. In contrast to cross point memory, the bitline can be made from the second hardmask (the hardmask, if left in place, would block the trim process in certain directions). The steps can be repeated to form several memory layers to increase device density.

Patterning of lines and spaces allows for reduced back sputtering and as a result enables patterning of higher aspect ratios. Patterning using lines and spaces also enables higher selectivity to the underlying layer. In some examples, selector devices and self-aligned refractory metal lines (for instance W) enable simple formation of cross point memory cells. Cross point MRAM cells can be stacked to further increase device density.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor substrate or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, substrate transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a substrate.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor substrates.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of substrates to and from tool locations and/or load ports in a semiconductor manufacturing factory.

What is claimed is:

1. A method for processing a substrate including a magnetoresistive random access memory (MRAM) stack, comprising:
providing a substrate including the MRAM stack;
creating a first mask layer on a surface of the MRAM stack,
wherein the first mask layer defines a first mask pattern including a first plurality of spaced mask lines extending in a first direction across the surface of the MRAM stack and first spaces located between the first plurality of spaced mask lines; and
performing ion beam etching in the first direction in the first spaces located between the first plurality of spaced mask lines to remove material of the MRAM stack located below the first spaces.

2. The method of claim 1, further comprising depositing gap fill material on the substrate.

3. The method of claim 2, wherein depositing the gap fill material on the substrate includes:
depositing a conformal silicon nitride layer on the substrate; and
depositing silicon dioxide layer on the silicon nitride layer.

4. The method of claim 2, wherein depositing the gap fill material on the substrate includes depositing a silicon nitride layer on the substrate.

5. The method of claim 2, further comprising removing overburden.

6. The method of claim 5, wherein removing the overburden comprises performing chemical mechanical polishing (CMP).

7. The method of claim 2, further comprising:
creating a second mask layer on the substrate,
wherein the second mask layer defines a second mask pattern including a second plurality of spaced mask lines that extend in a second direction across the surface of the MRAM stack and second spaces that are located between the second plurality of spaced mask lines, and
wherein the second direction is transverse to the first direction.

8. The method of claim 7, further comprising performing ion beam etching in the second direction in the second spaces located between the second plurality of spaced mask lines to remove material of the MRAM stack located below the second spaces and to create an array of rectangular MRAM stacks.

9. The method of claim 8, further comprising depositing gap fill material on the substrate between the MRAM stacks.

10. The method of claim 8, wherein depositing the gap fill material on the substrate includes:
depositing a conformal silicon nitride layer on the substrate; and
depositing silicon dioxide on the silicon nitride layer.

11. The method of claim 8, wherein depositing the gap fill material on the substrate includes depositing silicon nitride on the substrate.

12. The method of claim 11, further comprising removing overburden and the second mask pattern.

13. The method of claim 12, wherein the overburden and the second mask pattern are removed using chemical mechanical polishing (CMP).

14. The method of claim 12, further comprising using ion beam etching to trim between the array of rectangular MRAM stacks.

15. A method for processing a substrate including a magnetoresistive random access memory (MRAM) stack, comprising:
providing a substrate including a magnetoresistive random access memory (MRAM) stack arranged on an underlying layer;
creating a first mask layer on the substrate to define a first line and space mask pattern;
performing first ion beam etching in spaces of the first line and space mask pattern to create a plurality of spaced, elongate MRAM stacks that extend across the substrate;
creating a second mask layer to define a second line and space mask pattern arranged in a direction transverse to the first line and space mask pattern; and
performing second ion beam etching in spaces of the second line and space mask pattern to create an array of spaced, rectangular MRAM stacks on the substrate.

16. The method of claim 15, further comprising, prior to creating the second mask layer on the substrate, depositing gap fill material on the substrate and removing overburden.

17. The method of claim 16, wherein depositing the gap fill material on the substrate includes:
depositing a conformal silicon nitride layer on the substrate; and
depositing silicon dioxide layer on the silicon nitride layer.

18. The method of claim 16, wherein depositing the gap fill material on the substrate includes depositing a silicon nitride layer on the substrate.

19. The method of claim 18, further comprising, after performing the second ion beam etching, depositing gap fill material on the substrate between the array of spaced, rectangular MRAM stacks.

20. The method of claim 19, wherein depositing the gap fill material on the substrate includes:
depositing a conformal silicon nitride layer on the substrate; and
depositing silicon dioxide on the silicon nitride layer.

21. The method of claim 20, wherein depositing the gap fill material on the substrate includes depositing silicon nitride on the substrate.

22. The method of claim 19, further comprising removing overburden and the second mask layer.

23. The method of claim 22, further comprising using ion beam etching to trim between the array of spaced, rectangular MRAM stacks.
